(19) United States
(12) Patent Application Publication
(10) Pub. No.: US 2026/0234025 A1
(43) Pub. Date: Aug. 13, 2026

(54) METHOD FOR SINGLE-CRYSTALLIZATION REGENERATION OF WASTE CATHODE MATERIAL BY VACUUM PYROLYSIS PROCESS

(71) Applicant: KUNMING UNIVERSITY OF SCIENCE AND TECHNOLOGY, Kunming (CN)

(72) Inventors: Peng DONG, Kunming (CN); Qi MENG, Kunming (CN); Yingjie ZHANG, Kunming (CN); Zitong FEI, Kunming (CN); Xiaohui ZHAO, Kunming (CN)

(21) Appl. No.: 18/701,911

(22) PCT Filed: Dec. 20, 2023
(86) PCT No.: PCT/CN2023/140130

§ 371 Date: Apr. 16, 2024

(30) Foreign Application Priority Data
Nov. 1, 2023 (CN) 202311434349.1

(51) Int. Cl. C01G 53/502; H01M 10/54

(52) U.S. Cl. CPC C01G 53/502; H01M 10/54; C01P 2002/50; C01P 2002/72; C01P 2004/03; C01P 2006/40

(57) ABSTRACT

Provided is a method for single-crystallization regeneration of a waste cathode material by a vacuum pyrolysis process. The method includes: mixing a polycrystalline ternary cathode material of a waste lithium-ion battery, nickel stearate, and a lithium salt to be uniform to obtain a mixture, and subjecting the mixture to melting, and then vacuum calcination to obtain a regenerated single crystal ternary cathode material.

### CROSS-REFERENCE TO RELATED APPLICATION

The present application is a national stage application of International Patent Application No. PCT/CN2023/140130, filed on Dec. 20, 2023, which claims priority to a Chinese Patent Application No. CN202311434349.1, entitled “Method for single-crystallization regeneration of waste cathode material by vacuum pyrolysis process” filed with the China National Intellectual Property Administration (CNIPA) on Nov. 1, 2023. The disclosure of the two applications is incorporated herein by reference in its entirety.

### TECHNICAL FIELD

The present disclosure belongs to the technical field of recycling of waste lithium-ion cathode materials, and specifically relates to a method for single-crystallization regeneration of a waste cathode material by a vacuum pyrolysis process.

### BACKGROUND

Lithium-ion batteries are currently a new generation of secondary batteries with the highest energy density, which are widely used in mobile communications and digital technologies. In recent years, lithium-ion batteries have also been widely used in new energy vehicles and energy storage fields. Future demand for lithium-ion batteries and materials is difficult to estimate. A ternary layered lithium nickel manganese cobalt oxide (NMC) cathode material combines advantages of LiCoO₂, LiNiO₂, and LiMnO₂ cathode materials for lithium-ion batteries, where three transition metals have a significant synergistic effect. Ternary cathode materials have become cathode materials with great increase in the global market in recent years due to their advantages such as high energy density, long cycling life, and excellent safety. However, after nearly 1,000 cycles for a long period, the ternary cathode materials irreversibly reach “an endpoint of service life”. Scrapped lithium-ion batteries include a large amount of valuable metals such as lithium, nickel, cobalt, and manganese, and could be regarded as “man-made minerals” for extraction of metals. In addition, in China, lithium resources have problems such as difficult exploitation and purification, low output, and dependence on imports, and nickel ores have problems such as low grade and high exploitation cost, which results in high cost of re-synthesis of the ternary cathode material. If not reasonably recycled, lithium-ion batteries will become a major source of environmental pollution due to their heavy metal pollution and organic matter and fluorine pollution, which is not conducive to the concepts of comprehensive resource utilization and sustainable development. The recycling of scrapped lithium-ion batteries could not only allow the resource utilization of limited resources, and drive the development of cyclic economy, but also avoid the potential threat to human health and ecological environment, which has multiple benefits in resources, economy, society and so on. Therefore, the recycling and regeneration of scrapped lithium-ion batteries is of great significance and practical value.

Ternary cathode materials could be classified into single crystal type ternary cathode materials and polycrystalline type ternary cathode materials according to crystal structures. A polycrystal is composed of many single crystal particles with different orientations, and an entire crystal structure of the polycrystal is not penetrated by the same crystal lattice. A conventional polycrystalline ternary cathode material exists in the form of agglomeration of secondary spherical particles. The single crystal refers to a crystal produced through balanced growth of a crystal nucleus in all directions, and the internal structure of the single crystal is basically a complete crystal lattice. In single crystal technology, special precursors and sintering process is adopted so that the special structure of ternary cathode material for forming crystal is achieved; on the basis of maintaining the existing capacity and charge/discharge plateau of the cathode material, it is tried to improve a single crystal particle size of the cathode material, thereby improving a tap density of the cathode material, improving a volumetric capacity of a lithium battery, and greatly improving the safety of a lithium battery, which makes the quality of the lithium battery greatly improved. During a cycling process of a polycrystalline ternary cathode material, the accumulation of lattice strains and defects lead to lattice distortions, and the polycrystalline ternary cathode material is inevitably prone to grain boundary fractures (intergranular fractures). In addition, the contact of an electrolyte along grain boundaries and the cracking of secondary particles accelerate side reactions between a cathode and the electrolyte, such that a layered structure is transformed into a spinel structure, which ultimately leads to the attenuation of a voltage and a capacity. Furthermore, the expansion and contraction of particles will lead to the cracking and breakage of the entire secondary spheres, which will cause a drastic change of an electrochemical environment of a battery and thus shorten the cycling life of the battery. Due to weak connections among primary particles of a small single crystal, it is easy to cause the breakage of secondary particles and the deterioration of performance of a battery during a cold pressing process of an electrode sheet. A single crystal ternary cathode material is usually a primary irregular blocky particle directly composed of one or more large particles (2 μm to 5 μm). The single crystal ternary cathode material does not include grain boundaries inside, has a smooth microscopic surface, and exhibits excellent structural stability and high-temperature resistance. In addition, the single crystal ternary cathode material is not easy to break after compaction and high-temperature cycling, which allows excellent high-temperature cycling stability. Considering the high cost of re-synthesis of the ternary cathode material, regenerating waste polycrystalline cathode materials in single crystal form could not only reduce production cost, but also release a better internal structure, and repair a broken morphology compared with the traditional regeneration methods. A waste polycrystalline layered cathode material with defects can be transformed into a single crystal form for regeneration to obtain a single crystal layered cathode material with excellent structural performance. This technology not only shortens the recycling process, but also has great economic benefits and promising application prospects.

Patent application CN202110661097.0 entitled “method for single-crystallization regeneration of waste ternary cathode material” discloses that secondary particles of the waste ternary cathode material are pyrolyzed along grain boundaries into primary particles; the primary particles are subjected to molten salt calcination to make the primary particles nucleate and grow into single crystal particles; the molten salt are removed, and the ternary cathode material that has been grown into the single crystal particles are annealed to obtain a single crystal ternary cathode material. Patent application CN202210097582.4 entitled “method for single-crystallization of polycrystalline ternary cathode material” discloses that the ternary cathode material with polycrystalline morphology and a ball-milling agent are mixed to be uniform, and then added into a plasma ball mill and subjected to ball-milling, a resulting ball milled ternary cathode material is crush into small particles to obtain a plasma ball-milling product; the plasma ball-milling product is subjected to cleaning, suction filtering and oven-drying, then mixed with a lithium salt to be uniform, a resulting mixture is subjected to molten salt calcination to obtain a calcined cathode material; and the calcined cathode material is taken out, and subjected to washing with water, oven-drying, and annealing to finally obtain the single crystal ternary cathode material with an excellent crystallinity degree and a stable structure. Although the above two methods both could regenerate a polycrystalline cathode material of a waste ternary lithium-ion battery into a single crystal ternary cathode material, the method of the former patent application requires long-term high-temperature calcination to pyrolyze the polycrystalline cathode material into single crystal particles, and the method of the latter patent application adopts a ball-milling manner to pyrolyze the polycrystalline ternary cathode material into a single crystal cathode material, but a lithium supplementation process is conducted during the subsequent molten salt calcination, and annealing is also required subsequently, resulting in a too-cumbersome process.

The present disclosure is intended to provide a simple method for pyrolysis of a waste polycrystalline ternary cathode material into a single crystal ternary cathode material at a low calcination temperature.

### SUMMARY

An object of the present disclosure is to provide a method for single-crystallization regeneration of a waste cathode material by a vacuum pyrolysis process.

The object of the present disclosure is achieved by the following technical solutions. Provided is a method for single-crystallization regeneration of a waste cathode material by a vacuum pyrolysis process, including: mixing a polycrystalline ternary cathode material of a waste lithium-ion battery, nickel stearate, and a lithium salt to be uniform to obtain a mixture, and subjecting the mixture to melting, and then vacuum calcination to obtain a regenerated single crystal ternary cathode material,
where the lithium salt is a combination of lithium carbonate, lithium nitrate, and lithium sulfate, and a molar ratio of the lithium carbonate, the lithium nitrate, and the lithium sulfate is in a range of (3-5):(2-3):1; and
a mass ratio of the polycrystalline ternary cathode material of the waste lithium-ion battery, the nickel stearate, and the lithium salt is in a range of 1:(0.25-2):(0.4-1.1).

In some embodiments, the molar ratio of the lithium carbonate, the lithium nitrate, and the lithium sulfate is 4:3:1, 3:2:1, or 5:3:1.

In some embodiments, the combination of lithium carbonate, lithium nitrate, and lithium sulfate is replaced by lithium carbonate or lithium nitrate.

In some embodiments, the mass ratio of the polycrystalline ternary cathode material of the waste lithium-ion battery, the nickel stearate, and the lithium salt is 1:2:0.3.

In some embodiments, the method is specifically performed by the following steps:
1) mixing the polycrystalline ternary cathode material of the waste lithium-ion battery, the nickel stearate, and the lithium salt to obtain the mixture, and stirring and heating the mixture at a temperature of 90° C. to 120° C. for 8 h to 12 h to obtain a polycrystalline ternary cathode material of the waste lithium-ion battery with the nickel stearate partially penetrated;
2) placing the polycrystalline ternary cathode material of the waste lithium-ion battery with the nickel stearate partially penetrated in a vacuum atmosphere, heating to a temperature of 360° C. to 420° C. at a heating rate of 2° C./min to 10° C./min, and sintering at the temperature for 5 h to 8 h to obtain a waste single crystal ternary cathode material; and
3) mixing the waste single crystal ternary cathode material in a mortar to be uniform; in an oxygen atmosphere, calcining at a temperature of 400° C. to 450° C. for 3 h to 6 h, then heating to a temperature of 650° C. to 700° C. and calcining for 6 h to 12 h; subjecting a resulting calcined waste single crystal ternary cathode material to furnace-cooling, washing with water, suction filtration, and oven-drying at 80° C.; then calcining at a temperature of 650° C. to 700° C. for 2 h to 6 h in an oxygen atmosphere; and subjecting a resulting calcined material to furnace-cooling to obtain the regenerated single crystal ternary cathode material.

Some embodiments of the present disclosure have the following beneficial effects:
1. The method for single-crystallization regeneration of a waste cathode material by a vacuum pyrolysis process of the present disclosure could not only compensate for lithium loss of a waste single crystal ternary cathode material, but also convert insoluble residual Ni on a surface of the single crystal material during “explosion” process of nickel stearate into LiNiO₂ capable of providing a discharge capacity, which makes the regenerated cathode material exhibit excellent electrochemical performance and further reduces cost.
2. The method of the present disclosure is simple, safe and easy to operate, does not require ball milling, has a short period and low requirements for a temperature for regeneration reaction (a maximum temperature for calcination is merely 650° C.), and simultaneously allows the transformation of a polycrystalline into a single crystal and lithium supplementation without long-term high-temperature calcination. In the method of the present disclosure, residual nickel could also be reasonably converted to exert its value. In addition, the method of the present disclosure has low energy consumption and no pollution, and is suitable for popularization.

### BRIEF DESCRIPTION OF THE DRAWINGS

FIG. 1 shows a scanning electron microscopy (SEM) image of a polycrystalline ternary cathode material SNCM of a waste lithium-ion battery;

FIG. 2 shows an SEM image of the waste single crystal ternary cathode material SNCM-S in Example 1;

FIG. 3 shows an SEM image of the regenerated polycrystalline ternary cathode material RNCM in Comparative Example 1;

FIG. 4 shows an SEM image of the waste single crystal ternary cathode material SNCM-S1 in Comparative Example 2;

FIG. 5 shows an SEM image of the waste single crystal ternary cathode material SNCM-S2 in Comparative Example 3;

FIG. 6 shows an SEM image of the regenerated single crystal ternary cathode material RSNCM in Example 1;

FIG. 7 shows an SEM image of the regenerated single crystal ternary cathode material RSNCM-1 in Comparative Example 2;

FIG. 8 shows an SEM image of the regenerated single crystal ternary cathode material RSNCM-2 in Comparative Example 3;

FIG. 9 shows an SEM image of the regenerated single crystal ternary cathode material RSNCM-4 in Example 5;

FIG. 10 shows X-ray diffraction (XRD) patterns of the regenerated single crystal cathode material (RSNCM) prepared in Example 1 and the polycrystalline ternary cathode material (SNCM) of the waste lithium-ion battery; and

FIG. 11 shows electrochemical cycling performance curves of the regenerated single crystal cathode materials (RNCMs) prepared in Example 1 and Comparative Example 1, the regenerated cathode material (RSNCM-1) prepared in Comparative Example 2 and the polycrystalline ternary cathode material (SNCM) of the waste lithium-ion battery.

### DETAILED DESCRIPTION OF THE EMBODIMENTS

The present disclosure is further described in detail below in conjunction with the drawings and examples, but the present disclosure is not limited thereto in any way. Any transformation or replacement based on the teachings of the present disclosure falls within the scope of the present disclosure.

The present disclosure provides a method for single-crystallization regeneration of a waste cathode material by a vacuum pyrolysis process, including: mixing a polycrystalline ternary cathode material of a waste lithium-ion battery, nickel stearate, and a lithium salt to be uniform to obtain a mixture, and subjecting the mixture to melting, and then vacuum calcination to obtain a regenerated single crystal ternary cathode material,
where the lithium salt is a combination of lithium carbonate, lithium nitrate, and lithium sulfate, and a molar ratio of the lithium carbonate, the lithium nitrate, and the lithium sulfate is in a range of (3-5):(2-3):1; and
a mass ratio of the polycrystalline ternary cathode material of the waste lithium-ion battery, the nickel stearate, and the lithium salt is in a range of 1:(0.25-2):(0.4-1.1).

The method is specifically performed by the following steps:
1) mixing the polycrystalline ternary cathode material of the waste lithium-ion battery, the nickel stearate, and the lithium salt to obtain the mixture, and stirring and heating the mixture at a temperature of 90° C. to 120° C. for 8 h to 12 h to obtain a polycrystalline ternary cathode material of the waste lithium-ion battery with the nickel stearate partially penetrated;
2) placing the polycrystalline ternary cathode material of the waste lithium-ion battery with the nickel stearate partially penetrated in a vacuum atmosphere, heating to a temperature of 360° C. to 420° C. at a heating rate of 2° C./min to 10° C./min, and sintering at the temperature for 5 h to 8 h to obtain a waste single crystal ternary cathode material; and
3) mixing the waste single crystal ternary cathode material in a mortar to be uniform; in an oxygen atmosphere, calcining at a temperature of 400° C. to 450° C. for 3 h to 6 h, then heating to a temperature of 650° C. to 700° C. and calcining for 6 h to 12 h; subjecting a resulting calcined waste single crystal ternary cathode material to furnace-cooling, washing with water, suction filtration, and oven-drying at 80° C.; then calcining at a temperature of 650° C. to 700° C. for 2 h to 6 h in an oxygen atmosphere; and subjecting a resulting calcined material to furnace-cooling to obtain the regenerated single crystal ternary cathode material.

### Example 1

2 g of a polycrystalline ternary cathode material SNCM of a waste lithium-ion battery, 2 g of nickel stearate, and a combination of 0.738 g of Li₂CO₃, 0.517 g of LiNO₃, and 0.275 g of Li₂SO₄ (with a molar ratio being 4:3:1) were evenly mixed to obtain a mixture. The mixture was stirred at 100° C. for 10 h in an electric thermostatic oil bath, then heated to a temperature of 400° C. at a heating rate of 2° C./min and held at the temperature for 6 h in a vacuum environment of a tube furnace to obtain a waste single crystal ternary cathode material.

The waste single crystal ternary cathode material was evenly mixed in a mortar, and then calcined at 450° C. for 5 h in an oxygen atmosphere. A resulting material was heated to 650° C., and calcined for 12 h in an oxygen atmosphere to obtain a calcined material. The calcined material was subjected to washing with water, suction filtration, and oven-drying at 80° C. A resulting substance was calcined at 650° C. for 4 h in an oxygen atmosphere to obtain a solid, which was a regenerated single crystal ternary cathode material.

### Example 2

2 g of a polycrystalline ternary cathode material SNCM of a waste lithium-ion battery, 0.5 g of nickel stearate, and a combination of 0.738 g of Li₂CO₃, 0.738 g of LiNO₃, and 0.550 g of Li₂SO₄ (with a molar ratio being 2:2:1) were evenly mixed to obtain a mixture. The mixture was stirred at 120° C. for 8 h in an electric thermostatic oil bath, then heated to a temperature of 360° C. at a heating rate of 2° C./min and held at the temperature for 8 h in a vacuum environment of a tube furnace to obtain a waste single crystal ternary cathode material.

The waste single crystal ternary cathode material was evenly mixed in a mortar, and then calcined at 400° C. for 4 h in an oxygen atmosphere. A resulting material was heated to 700° C., and calcined for 10 h in an oxygen atmosphere to obtain a second calcined material. The calcined material was subjected to washing with water, suction filtration, and oven-drying at 80° C. A resulting substance was calcined at 700° C. for 2 h in an oxygen atmosphere to obtain a regenerated single crystal ternary cathode material.

### Example 3

2 g of a polycrystalline ternary cathode material SNCM of a waste lithium-ion battery, 1 g of nickel stearate, and a combination of 0.246 g of Li₂CO₃, 0.460 g of LiNO₃, and 0.366 g of Li₂SO₄ (with a molar ratio being 3:2:1) were evenly mixed to obtain a mixture. The mixture was stirred at 110° C. for 10 h in an electric thermostatic oil bath, then heated to a temperature of 380° C. at a heating rate of 2° C./min and held at the temperature for 7 h in a vacuum environment of a tube furnace to obtain a waste single crystal ternary cathode material.

The waste single crystal ternary cathode material was evenly mixed in a mortar, and then calcined at 425° C. for 6 h in an oxygen atmosphere. A resulting material was heated to 650° C., and calcined for 8 h in an oxygen atmosphere to obtain a second calcined material. The calcined material was subjected to washing with water, suction filtration, and oven-drying at 80° C. A resulting substance was calcined at 650° C. for 6 h in an oxygen atmosphere to obtain a regenerated single crystal ternary cathode material.

### Example 4

2 g of a polycrystalline ternary cathode material SNCM of a waste lithium-ion battery, 4 g of nickel stearate, and a combination of 0.739 g of Li₂CO₃, 0.414 g of LiNO₃, and 0.220 g of Li₂SO₄ (with a molar ratio being 5:3:1) were evenly mixed to obtain a mixture. The mixture was stirred at 90° C. for 12 h in an electric thermostatic oil bath, then heated to a temperature of 420° C. at a heating rate of 2° C./min and held at the temperature for 5 h in a vacuum environment of a tube furnace to obtain a waste single crystal ternary cathode material.

The waste single crystal ternary cathode material was evenly mixed in a mortar, and then calcined at 450° C. for 5 h in an oxygen atmosphere. A resulting material was heated to 650° C., and calcined for 12 h in an oxygen atmosphere to obtain a calcined material. The calcined material was subjected to washing with water, suction filtration, and oven-drying at 80° C. A resulting substance was calcined at 700° C. for 6 h in an oxygen atmosphere to obtain a pretreated regenerated single crystal cathode material. The pretreated regenerated single crystal cathode material was subjected to washing with water, and drying. A resulting cathode material was calcined at 700° C. for 4 h in an oxygen atmosphere to obtain a regenerated single crystal ternary cathode material.

### Example 5

The method in this example was basically the same as the method in Example 1, except that 0.8 g of lithium carbonate (Li₂CO₃) was adopted as a lithium salt.

### Example 6

The method in this example was basically the same as the method in Example 1, except that 0.6 g of lithium nitrate (LiNO₃) was adopted as a lithium salt.

### Comparative Example 1

This comparative example was basically the same as Example 1, except that no nickel stearate was added.

### Comparative Example 2

This comparative example was basically the same as Example 1, except that the heating rate in the vacuum environment was 5° C./min.

### Comparative Example 3

This comparative example was basically the same as Example 1, except that the heating rate in the vacuum environment was 10° C./min.

### Test Example 1

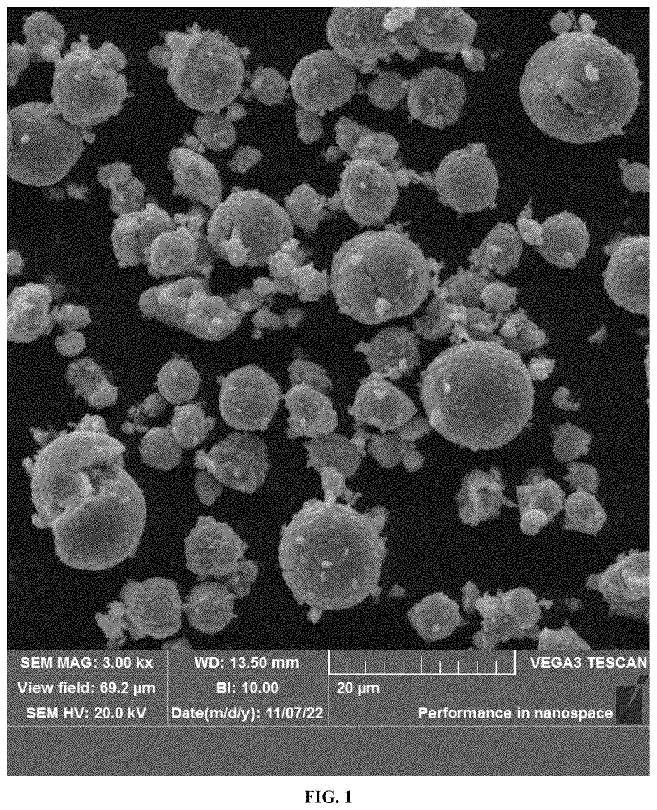

The waste single crystal cathode materials and the regenerated cathode materials prepared in Examples 1 and 5 and Comparative Examples 1, 2, and 3 each were subjected to SEM test. The test results are shown in FIG. 1 to FIG. 9.

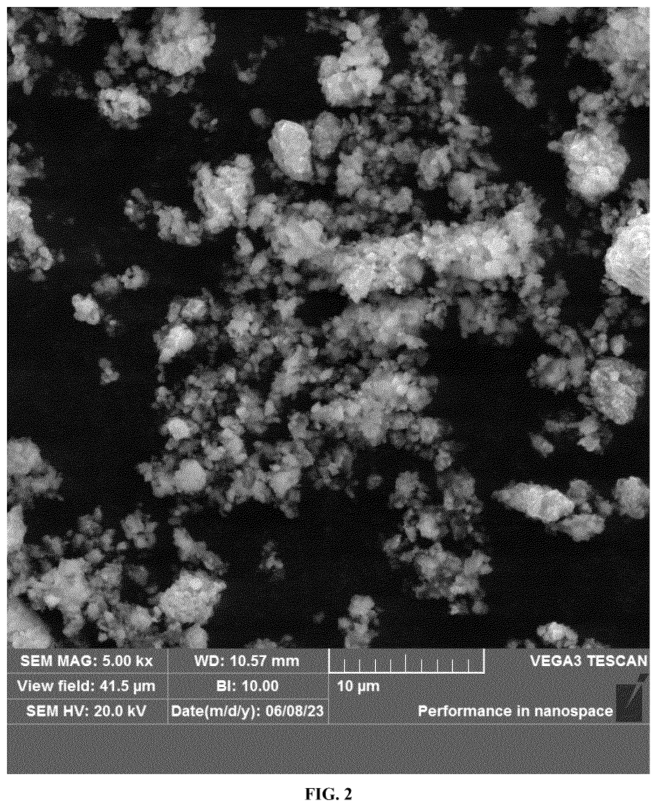

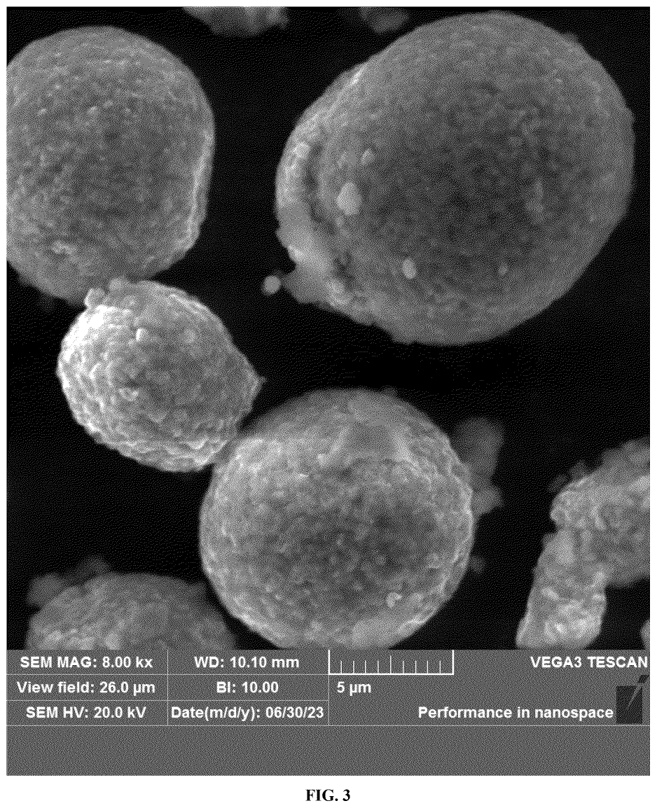

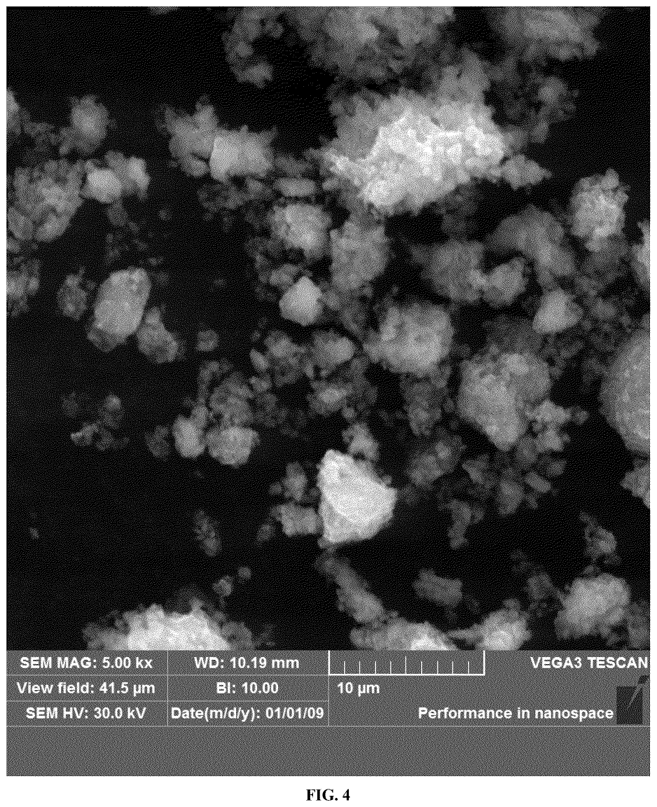

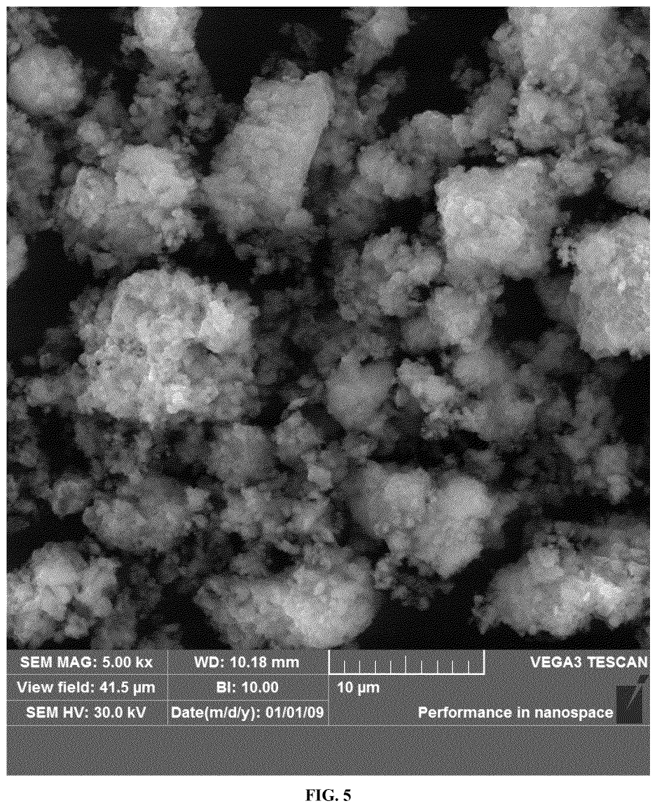

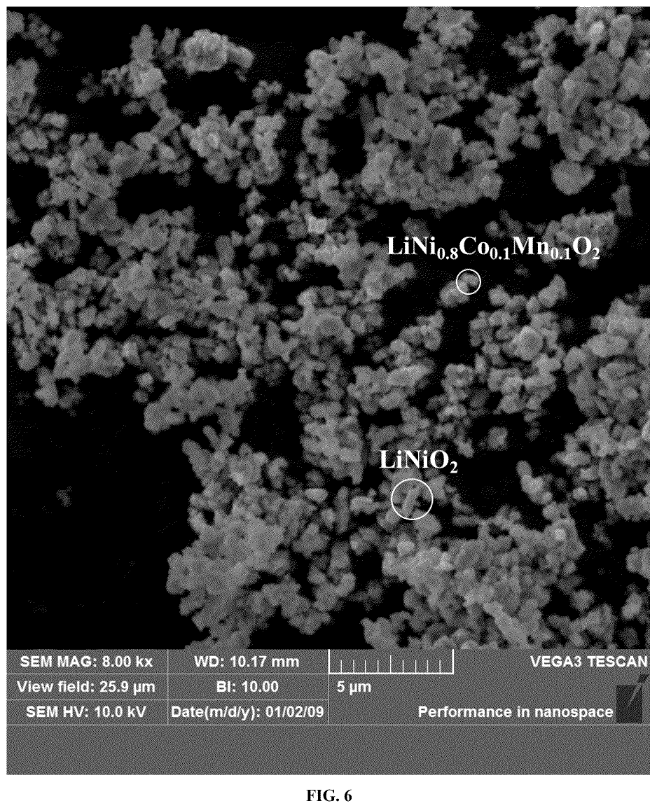

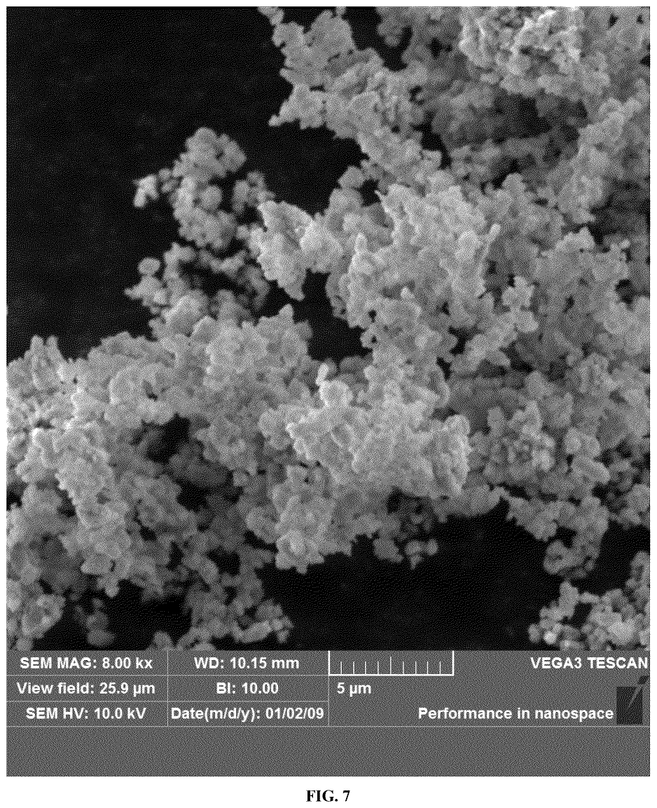

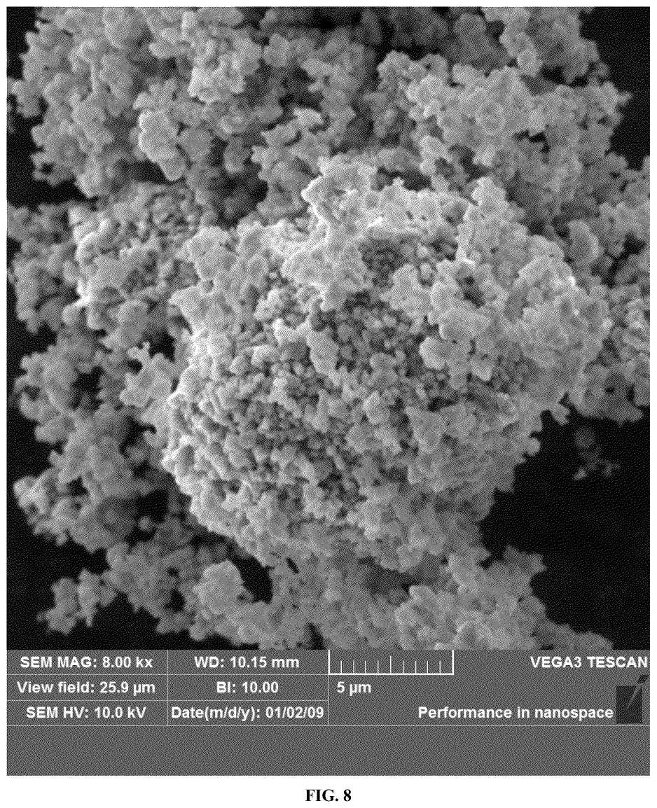

It can be seen from FIG. 1 to FIG. 9 that the polycrystalline ternary cathode material SNCM of the waste lithium-ion battery (FIG. 1) is composed of spheroidic secondary particles produced through accumulation of primary particles, has a particle size of 8 nm to 10 nm, and has cracks and white flocci on its surface, where the white flocci may be residual polyvinylidene fluoride (PVDF) and conductive carbon. The waste single crystal cathode material obtained in Example 1 (FIG. 2) is “exploded” into a large-area of independent primary particles, while the material obtained in Comparative Example 1 (FIG. 3) is still presented as secondary particles, that is, the material is not “exploded” into single crystal particles, and a surface of the material has microcracks and is not completely repaired. Whereas, the “exploded” waste single crystal cathode material particles obtained in Comparative Examples 2 and 3 still retain large spheroidic secondary particles (FIG. 4 and FIG. 5), indicating that a too-high heating rate could not fully ensure the excellent “explosion” of polycrystalline particles into primary particles. The regenerated single crystal cathode material obtained by regeneration in Example 1 (FIG. 6) is presented as primary particles, has a smooth surface without cracks and impurities, and includes single crystal LiNiO₂ at the same time, and the synthesized single crystal LiNiO₂ is presented as a long strip-shaped primary particle significantly different from primary particles of a ternary material and has a smooth surface without impurities and cracks. Whereas, in Comparative Examples 2 and 3, there is no excellent “explosion” into primary particles during a single-crystallization process (FIG. 7 and FIG. 8), there is large-area agglomeration in a regenerated material, and the synthesized LiNiO₂ and the single crystal ternary cathode material are agglomerated together and attached to a surface of an unexploded polycrystalline material, which is not conducive to the deintercalation of lithium ions, will greatly affect the electrochemical performance of the regenerated material, and could not meet the material requirements.

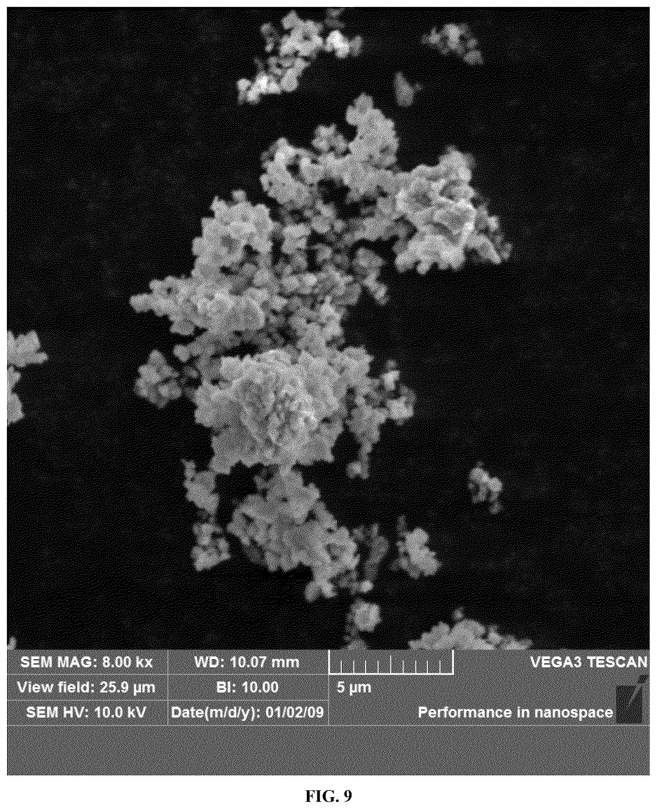

The regenerated cathode material (FIG. 9) obtained by regeneration with lithium carbonate (Li₂CO₃) as a single lithium source in Example 5 has no microcracks, a relatively-clear crystal plane, and an agglomeration phenomenon in a small range, and a small amount of the lithium salt is attached to the regenerated cathode material, which increases the lithium ion transmission resistance and leads to a lower repair degree for the cathode material than in Example 1.

### Test Example 2

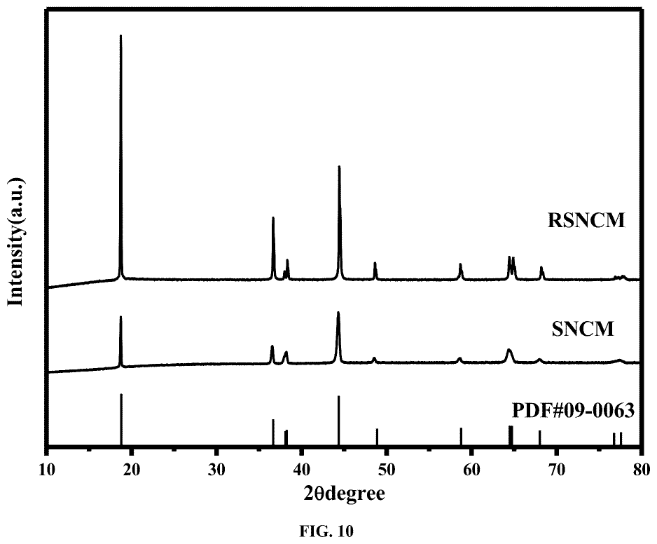

The polycrystalline ternary cathode material (SNCM) of the waste lithium-ion battery and the regenerated single crystal cathode material (RSNCM) prepared in Example 1 each were subjected to XRD test. The test results are shown in FIG. 10.

It can be seen from FIG. 10 that XRD patterns of SNCM and RSNCM have similar diffraction peaks, and are basically in agreement with a LiNiO₂ standard pattern PDF #09-0063, indicating a typical hexagonal layered LiNiO₂ structure with an R-3m space group. Diffraction peaks of SNCM are more smooth than diffraction peaks of RSNCM, where (006) and (012) are merged, (108) and (110) are merged, and splitting is not obvious, indicating that the waste polycrystalline cathode material (SNCM) has a reduced crystallinity degree and a crystal structure damaged to some extent, which may be caused by an irreversible phase transition during a charge/discharge process. The XRD pattern of the regenerated RSNCM has sharp diffraction peaks, where (006)/(012) characteristic diffraction peaks and (108)/(110) characteristic diffraction peaks are split significantly, indicating that the regenerated RSNCM has a prominent layered structure, and the sharp diffraction peaks also indicate the large restoration of a crystallinity degree of the regenerated RSNCM. In addition, no impurity peak is found in the XRD pattern of SRNCM, indicating that the method of the present disclosure does not introduce new impurity phases and a compound of residual Ni on a surface is efficiently converted into LiNiO₂ capable of providing a capacity, which is consistent with the SEM analysis result in FIG. 5.

### Test Example 3

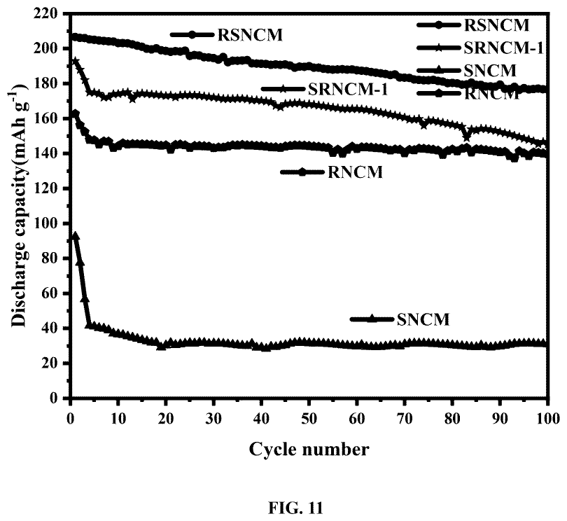

The polycrystalline ternary cathode material (SNCM) of the waste lithium-ion battery, the regenerated single crystal cathode material (RSNCM) prepared in Example 1, the regenerated cathode material (RNCM) prepared in Comparative Example 1, and the regenerated single crystal cathode material (RSNCM-1) prepared in Comparative Example 2 each were subjected to cycling performance test. Results of the cycling performance test are shown in Table 1 and FIG. 11.

The results show that the regenerated single crystal ternary cathode material (RSNCM) in Example 1 has a first-cycle specific discharge capacity of 206.198 mAh g⁻¹ that is significantly higher than the 162.687 mAh g⁻¹ of the regenerated cathode material (RNCM) prepared in Comparative Example 1 and the 192.772 mAh g⁻¹ of the regenerated single crystal cathode material RSNCM-1 in Comparative Example 2, which is due to the fact that LiNiO₂ converted from residual Ni could provide a partial capacity, and at the same time, the capacity of the original waste single crystal cathode material is restored after sufficient lithium compensation. After 100 cycles, a capacity retention rate of RSNCM is 86.7%, which is significantly higher than capacity retention rates of the regenerated cathode material (RNCM) prepared in Comparative Example 1 and the regenerated single crystal cathode material (RSNCM-1) prepared in Comparative Example 2, indicating that the electrochemical performance of the material is restored and could meet the service requirements.

TABLE 1
Charge/discharge test results of the regenerated cathode materials prepared in
Example 1 and Comparative Examples 1 and 2

| | Specific discharge | Specific discharge | Cycling retention |
|---|---|---|---|
| | capacity after 1 cycle | capacity after 100 cycles | rate after 100 |
| Sample | (mAh g⁻¹) | (mAh g⁻¹) | cycles (%) |
| Polycrystalline ternary | 92.467 | 30.861 | 33.3% |
| cathode material SNCM | | | |
| of a waste lithium-ion | | | |
| battery | | | |
| RSNCM of Example 1 | 206.020 | 176.585 | 86.7% |
| RNCM of Comparative | 162.687 | 139.646 | 85.8% |
| Example 1 | | | |
| RSNCM-1 of | 192.772 | 145.282 | 75.4% |
| Comparative Example 2 | | | |

Although the present disclosure is described in detail in conjunction with the foregoing embodiments, they are only a part of, not all of, the embodiments of the present disclosure. Other embodiments can be obtained based on these embodiments without creative efforts, and all of these embodiments shall fall within the scope of the present disclosure.

1. A method for single-crystallization regeneration of a waste cathode material by a vacuum pyrolysis process, comprising:
mixing a polycrystalline ternary cathode material of a waste lithium-ion battery, nickel stearate, and a lithium salt to be uniform to obtain a mixture, and subjecting the mixture to melting and then vacuum calcination to obtain a regenerated single crystal ternary cathode material,
wherein the lithium salt is a combination of lithium carbonate, lithium nitrate, and lithium sulfate, and a molar ratio of the lithium carbonate, the lithium nitrate, and the lithium sulfate is in a range of (3-5):(2-3):1; and
a mass ratio of the polycrystalline ternary cathode material of the waste lithium-ion battery, the nickel stearate, and the lithium salt is in a range of 1:(0.25-2):(0.4-1.1).

2. The method for single-crystallization regeneration of the waste cathode material by the vacuum pyrolysis process of claim 1, wherein the molar ratio of the lithium carbonate, the lithium nitrate, and the lithium sulfate is 4:3:1, 3:2:1, or 5:3:1.

3. The method for single-crystallization regeneration of the waste cathode material by the vacuum pyrolysis process of claim 1, wherein the combination of lithium carbonate, lithium nitrate, and lithium sulfate is replaced by lithium carbonate or lithium nitrate.

4. The method for single-crystallization regeneration of the waste cathode material by the vacuum pyrolysis process of claim 1, wherein the mass ratio of the polycrystalline ternary cathode material of the waste lithium-ion battery, the nickel stearate, and the lithium salt is 1:2:0.3.

5. The method for single-crystallization regeneration of the waste cathode material by the vacuum pyrolysis process of claim 1, wherein the method is specifically performed by the following steps:
1) mixing the polycrystalline ternary cathode material of the waste lithium-ion battery, the nickel stearate, and the lithium salt to obtain the mixture, and stirring and heating the mixture at a temperature of 90° C. to 120° C. for 8 h to 12 h to obtain a polycrystalline ternary cathode material of the waste lithium-ion battery with the nickel stearate partially penetrated;
2) placing the polycrystalline ternary cathode material of the waste lithium-ion battery with the nickel stearate partially penetrated in a vacuum atmosphere, heating to a temperature of 360° C. to 420° C. at a heating rate of 2° C./min to 10° C./min, and sintering at the temperature for 5 h to 8 h to obtain a waste single crystal ternary cathode material; and
3) mixing the waste single crystal ternary cathode material in a mortar to be uniform; in an oxygen atmosphere, calcining at a temperature of 400° C. to 450° C. for 3 h to 6 h, then heating to a temperature of 650° C. to 700° C. and calcining for 6 h to 12 h; subjecting a resulting calcined waste single crystal ternary cathode material to furnace-cooling, washing with water, suction filtration, and oven-drying at 80° C.; then calcining at a temperature of 650° C. to 700° C. for 2 h to 6 h in an oxygen atmosphere; and subjecting a resulting calcined material to furnace-cooling to obtain the regenerated single crystal ternary cathode material.

6. The method for single-crystallization regeneration of the waste cathode material by the vacuum pyrolysis process of claim 2, wherein the combination of lithium carbonate, lithium nitrate, and lithium sulfate is replaced by lithium carbonate or lithium nitrate.

7. The method for single-crystallization regeneration of the waste cathode material by the vacuum pyrolysis process of claim 2, wherein the mass ratio of the polycrystalline ternary cathode material of the waste lithium-ion battery, the nickel stearate, and the lithium salt is 1:2:0.3.
